(19) United States
(12) Patent Application Publication
(10) Pub. No.: US 2014/0264340 A1
(43) Pub. Date: Sep. 18, 2014

(54) REVERSIBLE HYBRIDIZATION OF LARGE SURFACE AREA ARRAY ELECTRONICS

(71) Applicant: Sandia Corporation, Albuquerque, NM (US)

(72) Inventors: Seethambal S. Mani, Albuquerque, NM (US); Nathan Paul Young, Fairfield, CA (US)

(73) Assignee: Sandia Corporation, Albuquerque, NM (US)

(21) Appl. No.: 14/208,176

(22) Filed: Mar. 13, 2014

Related U.S. Application Data
(60) Provisional application No. 61/785,367, filed on Mar. 14, 2013.

(51) Int. Cl. H01L 21/66; H01L 23/00; H01L 25/065

(52) U.S. Cl. CPC H01L 22/32; H01L 22/14; H01L 25/0657; H01L 24/29
USPC 257/48; 438/15; 257/777; 257/741

(57) ABSTRACT

Various technologies pertaining to characterizing a component of a large surface area array electronic device, such as a focal plane array (FPA), are described. A first semiconductor chip is reversibly hybridized with a second semiconductor chip through use of a conductive layer. Responsive to being reversibly hybridized, at least one of the first semiconductor chip or the second semiconductor chip is characterized as being defective or suitable for deployment. Thereafter, the conductive layer is removed, and the first semiconductor chip is separated from the second semiconductor chip without damaging either of the first semiconductor chip or the second semiconductor chip.

### RELATED APPLICATION

This application claims priority to U.S. Provisional Patent Application No. 61/785,367, filed on Mar. 14, 2013, and entitled “REVERSIBLE FOCAL PLANE ARRAY HYBRIDIZATION”, the entirety of which is incorporated herein by reference.

### STATEMENT OF GOVERNMENTAL INTEREST

This invention was developed under Contract DE-AC04-94AL85000 between Sandia Corporation and the U.S. Department of Energy. The U.S. Government has certain rights in this invention.

### BACKGROUND

Conventionally, it is difficult to test large surface array electronics prior to such devices being subjected to the hybridization. For example, a focal plane array (FPA) includes a detector and a readout integrated circuit (ROIC), where the detector and the ROIC are hybridized to form a portion of the FPA. The hybridization process includes permanently mechanically and electrically bonding the detector and the ROIC through use of metallic bonds between conductive contacts of the detector and conductive contacts of the ROIC. In some cases, prior to hybridization, the ROIC may be well-characterized, and may be known to meet operational standards. Conventional testing of the detector prior to hybridization, however, is less exhaustive. For example, typically, a relatively small number of pixels of the detector are tested, and the performance of the pixels is extrapolated and used to characterize the entirety of the detector.

After the detector has been hybridized with the ROIC, the combination of the detector and ROIC can be tested prior to being included in the FPA. During this stage of testing, if it is determined that the combination fails to meet operational standards (e.g., due to detector defects not identified prior to hybridization), then the hybridized detector and ROIC are shelved or discarded, as it is difficult to mechanically separate the detector from the ROIC without damaging the detector, the ROIC, or both the detector and the ROIC. This can be relatively costly for several reasons: 1) time and resources have been devoted to ascertaining that the ROIC meets operational standards; and 2) while processes exist for repairing defective pixels in detectors prior to hybridization, such processes are not well suited for repairing defective pixels in detectors after the detectors have been hybridized with a ROIC. In an example, for large surface area FPAs (e.g., for deployment in orbiting satellites), development costs can be in the range of between five million and fifty million dollars, with a non-insignificant portion of such costs attributable to resources lost due to the lack of suitable mechanisms to characterize detectors as being defective or meeting operational standards prior to hybridizing the detectors with respective ROICs.

### SUMMARY

The following is a brief summary of subject matter that is described in greater detail herein. This summary is not intended to be limiting as to the scope of the claims.

Described herein are various technologies pertaining to testing and characterization of componentry of large surface area array electronics by way of reversibly hybridizing such componentry with other componentry. In an exemplary embodiment, an electronic device, when operating, can comprise a first semiconductor chip that is hybridized with a second semiconductor chip. It may be desirable to characterize the first semiconductor chip as being one of defective or suitable for deployment prior to the first semiconductor chip and the second semiconductor chip being permanently hybridized. Pursuant to an example, the first semiconductor chip can comprise a readout integrated circuit (ROIC) and the second semiconductor chip can comprise a detector (wherein the detector comprises an array of photodetectors). The first semiconductor chip comprises first conductive contacts at first respective locations on the first semiconductor chip, and the second semiconductor chip comprises second conductive contacts at respective second locations on the second semiconductor chip. When hybridized, the first conductive contacts of the first semiconductor are mechanically and electrically bonded, respectively, with the second conductive contacts of the second semiconductor chip.

As is described herein, a conductive layer can be used to reversibly hybridize the first semiconductor chip with the second semiconductor chip, where the first conductive contacts of the first semiconductor chip are mechanically and electrically bonded, respectively, with the second conductive contacts of the second semiconductor chip by way of the conductive layer. In an exemplary embodiment, the conductive layer can be a re-workable anisotropic conductive film adhesive (ACFA). In another exemplary embodiment, the conductive layer can be a conductive polymer, such as polyaniline. When the conductive layer is the ACFA, the ACFA can be manufactured such that conductive paths extend through the thickness of the ACFA at particular positions. In operation, the first semiconductor chip (e.g., the ROIC) can be stably positioned on a platform, and the ACFA can be relatively precisely aligned with the first semiconductor chip, such that the conductive paths of the ACFA are respectively placed in physical contact with the first conductive contacts of the first semiconductor chip. When the conductive layer is the conductive polymer, the conductive polymer can be applied to the first semiconductor chip, and subsequently patterned based upon the respective first locations of the first conductive contacts of the first semiconductor chip and the respective second locations of the second conductive contacts of the second semiconductor chip (e.g., the detector). In an example, photolithography can be employed when patterning the conductive polymer.

Responsive to the conductive layer being appropriately aligned and/or patterned relative to the first semiconductor chip, the second semiconductor chip can be relatively precisely aligned with and placed upon the conductive layer, such that the conductive layer is between the first semiconductor chip and the second semiconductor chip. When the conductive layer is the ACFA, the second semiconductor chip is aligned with the ACFA such that the second conductive contacts of the second semiconductor chip are in physical contact with the conductive pathways that extend through the ACFA. Accordingly, the first contacts of the first semiconductor chip are respectively electrically coupled with the second contacts of the second semiconductor chip by way of the conductive pathways. Through application of compressive pressure to the ACFA and/or through application of heat to the ACFA, the ACFA can be cured, and the first semiconductor chip can be electrically and mechanically bonded (e.g., hybridized) with the second semiconductor chip.

When the conductive layer is the patterned conductive polymer, the second semiconductor chip is aligned such that the second contacts are placed in physical contact with portions of the conductive polymer not removed during the aforementioned patterning. That is, the conductive polymer is patterned such that individualized conductive pathways are formed for the first contacts and the second contacts of the semiconductor devices. When aligned in this manner, respective conductive pathways are formed between the first contacts of the first semiconductor device and the second contacts of the second semiconductor device (e.g., the first semiconductor device is hybridized with the second semiconductor device).

Responsive to the first semiconductor chip and the second semiconductor chip becoming (reversibly) hybridized, the first semiconductor chip and/or the second semiconductor chip can be tested and characterized. For example, the first semiconductor chip can be a ROIC that is a priori characterized as being suitable for deployment (e.g., a “gold standard” ROIC). The second semiconductor chip can be a detector that is desirably characterized, and the ROIC can be reversibly hybridized with the detector by way of the conductive layer. The resultant device can then be subjected to testing, wherein the testing can cause currents generated by photodetectors to travel over respective conductive paths in the conductive layer to the ROIC. Based upon such currents, the detector can be characterized as being suitable for operation or defective (as the ROIC has already been characterized as being operational).

Responsive to testing being completed, the conductive layer can be removed, thereby electrically and mechanically separating the first semiconductor chip from the second semiconductor chip (e.g., without damaging either the first semiconductor chip or the second semiconductor chip). For example, the conductive layer can dissolve when a solvent is introduced to the conductive layer. In another example, the conductive layer may evaporate when a particular amount of heat is applied thereto (e.g., where the heat is low enough to refrain from damaging either the first semiconductor chip or the second semiconductor chip). In still yet another example, application of force to the conductive layer may cause the conductive layer to release from at least one of the first semiconductor chip or the second semiconductor chip. It is to be understood that any combination of solvent, heat, and force can be applied when de-hybridizing the first semiconductor chip and the second semiconductor chip. When the second semiconductor chip is found to be defective, the second semiconductor may be subjected to a repair process (e.g., annealing). This is possible, as the detector is no longer mechanically bonded with the first semiconductor chip. Therefore, prior to assembling an FPA, for instance, each detector to be included therein can be characterized as being suitable for operation, thus increasing yield and reducing cost.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1 illustrates an exemplary system that is configured to characterize a component of a large surface area array electronic device.

FIG. 2 illustrates application of a conductive layer to a first semiconductor chip.

FIG. 3 is a cross-sectional view of a portion of a conductive layer when the conductive layer is an anisotropic conductive film adhesive (ACFA).

FIG. 4 illustrates the forming of electrical and mechanical bonds between respective conductive contacts of a first semiconductor chip and a second semiconductor chip by way of a conductive layer.

FIG. 5 illustrates a conductive path formed between a first contact of a first semiconductor chip and a second contact of a second semiconductor chip by way of an ACFA.

FIG. 6 illustrates a stacked electronic device that is reversibly hybridized by way of a conductive layer.

FIG. 7 depicts removal of a conductive layer from between a first semiconductor chip and a second semiconductor chip without damaging either the first semiconductor chip or the second semiconductor chip.

FIG. 8 illustrates the mechanical and electrical separation of a first semiconductor chip from a second semiconductor chip.

FIG. 9 is a flow diagram that illustrates an exemplary methodology for characterizing a component of a large surface area array electronic device.

FIG. 10 is a flow diagram illustrating an exemplary methodology for reversibly hybridizing a detector and a readout integrated circuit (ROIC) for purposes of characterizing the detector.

### DETAILED DESCRIPTION

Various technologies pertaining to characterizing a component of a large surface area array electronic device are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects.

Moreover, the term “or” is intended to be an inclusive “or” rather than an exclusive “or.” That is, unless specified otherwise, or clear from the context, the phrase “X employs A or B” is intended to mean any of the natural inclusive permutations. Thus, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Described herein are various technologies related to characterizing a component of a large surface area array electronic device by way of forming reversible mechanical and electrical bonds between components of such electronic device. In an exemplary embodiment, the large surface area array electronic device can be a focal plane array (FPA), and a desirably characterized component of the device can be a detector that forms a portion of the FPA, wherein the detector comprises a plurality of pixels. In another exemplary embodiment, the electronic device can be a three-dimensional memory array, and a desirably characterized component of the device can be a memory chip that comprises a plurality of storage units (e.g., where the device includes several stacked memory chips). Furthermore, a desirably characterized component of a large surface area array electronic device can be a field programmable gate array (FPGA) or other suitable component that has a relatively large number of units.

With respect to FPAs, an exemplary FPA can comprise multiple detectors, each detector comprising an array of pixels. Conventionally, detectors undergo limited testing prior to being mated (hybridized) to a corresponding readout integrated circuit (ROIC). For large surface area FPAs, fabricating componentry (such as ROICs) requires a relatively large volume of resources. Currently, testing of a detector includes testing performance of a relatively small number of pixels in the array, and behavior of the small number of pixels is extrapolated to the larger array. Testing in this manner can result in the detector being mischaracterized (e.g., a defective detector can be characterized as being suitable for deployment, potentially resulting in assembly of an FPA that fails to meet defined operational standards).

It can therefore be ascertained that performance and assembly yield of an FPA manufacturing process is improved if a well-characterized detector is mated with a well-characterized ROIC. Described herein are various technologies related to the use of a conductive layer to temporarily and reversibly hybridize a first semiconductor chip (e.g., a ROIC) with a second semiconductor chip (e.g., a detector), such that at least one of the first semiconductor chip or the second semiconductor chip can be characterized prior to permanently hybridizing the at least one of the first semiconductor chip or the second semiconductor chip with a corresponding component. Thus, for instance, a large area detector can be tested and characterized prior to being committed to a highly valued and characterized integrated ROIC unit.

With reference now to FIG. 1, an exemplary system 100 that facilitates testing and characterizing at least one component of a large surface area array electronic device is illustrated. The system 100 includes a device 102 that comprises a first semiconductor chip 104, a second semiconductor chip 106, and a conductive layer 108 that is positioned between the first semiconductor chip 104 and the second semiconductor chip 106. As will be described in greater detail herein, the conductive layer 108 can be an anisotropic conductive film adhesive (ACFA) or a layer of a (organic) conductive polymer, such as polyaniline. The first semiconductor chip 104 comprises first conductive contacts 110a-110d (collectively referred to as first contacts 110), wherein the first contacts 110 are at respective first positions on the upper side of the first semiconductor chip 104. While a number of contacts in the first contacts 110 is shown as being four, it is to be understood that the number of contacts in the first contacts 110 in practice will be much greater than four (e.g., between one thousand and ten million contacts). The first semiconductor chip 104 can have a bond pad 111, where the bond pad 111 is in electrical communication with the first contacts 110 of the first semiconductor chip 104. The bond pad 111 is exposed, such that the bond pad 111 can be directly contacted (e.g., the conductive layer 108 need not cover the bond pad 111).

The conductive layer 108 comprises conductive pathways 113a-113d (collectively referred to as conductive pathways 113) that extend through the height of the conductive layer 108. When the conductive layer 108 comprises the ACFA, the conductive pathways 113 can be positioned in the ACFA at particular positions and angular directions during manufacture of the ACFA. Such positions and angular directions can be based upon known positions of the first contacts 110 of the first semiconductor chip 104 relative to corresponding contacts of the second semiconductor chip 106. When the conductive layer 108 is the conductive polymer layer, the conductive polymer can be patterned, such that the subsequent to completion of the patterning, the conductive pathways 113 remain.

The second semiconductor chip 106 comprises second conductive contacts 112a-112d (collectively referred to as second contacts 112), wherein (when oriented as shown in FIG. 1) the second contacts 112 are at second respective locations on the lower side of the second semiconductor chip 106. Again, while a number of contacts in the second contacts 112 is shown as being four, it is to be understood that, practically, the number of contacts in the second contacts 112 will be much greater than four (e.g., between one thousand and ten million contacts). When the second semiconductor chip 106 is aligned with and placed on the conductive layer 108, the second contacts 112 of the second semiconductor chip 106 are oriented to oppose the first contacts 110 by way of the conductive layer, such that the conductive layer 108 is in physical contact with the second contacts 112.

The system 100 includes a platform 116 upon which the device 102 can be stably positioned. The system 100 may further include a placement tool 118 that is configured to align the second semiconductor chip 106 with conductive layer 108 and place the second semiconductor 106 on the conductive layer 108 when properly aligned therewith. When properly aligned, the second contacts 112 are respectively in contact with the conductive pathways 113, and are thus respectively electrically coupled with the first contacts 110. The placement tool 118 can be any suitable device used in semiconductor processing to align and stack semiconductor chips. The system 100 may further include a computing device 120 that is electrically coupled to the device 102 by way of the bond pad 111 of the first semiconductor chip 104. The computing device 120 can receive electrical signals output by the first semiconductor chip 104, and can analyze the signals to characterize at least one of the first semiconductor chip 104 or the second semiconductor chip 106 as being suitable for operation or defective.

In an exemplary embodiment, when the conductive layer 108 comprises the ACFA, the device 102 can be formed by stabilizing the first semiconductor chip 104 onto the platform 116, and subsequently aligning the ACFA with the first semiconductor chip 104 based upon locations of the first contacts 110 on the upper side of the first semiconductor chip 104. As noted above, the ACFA can be manufactured to include the conductive pathways 113, and the ACFA can be aligned with and placed on the first semiconductor chip 104 such that the conductive pathways 113 respectively electrically contact the first contacts 110.

When the conductive layer 108 comprises the conductive polymer, the conductive polymer can be applied to the upper side of the first semiconductor chip 104, such that the conductive polymer contacts the first contacts 110. Responsive to the conductive polymer being applied to the upper side of the first semiconductor chip 104, the conductive polymer can be patterned based upon the respective first locations of the first contacts 110 of the first semiconductor chip 104 and the respective second locations of the second contacts 112 of the second semiconductor chip 106 (thus forming the conductive pathways 113). In an example, photolithography can be employed when patterning the conductive polymer.

The placement tool 118 can then be employed to align the second semiconductor chip 106 with the conductive layer 108, such that the second contacts 112 of the second semiconductor chip 106 are aligned with the respective conductive pathways 113. The placement tool 118 can then place the second semiconductor chip 106 on the conductive layer 108, such that the second contacts 112 of the second semiconductor chip 106 contact the respective conductive pathways 113. Accordingly, the second contacts 112 are electrically coupled to the first contacts 110 by way of individualized conductive pathways (e.g., the first semiconductor chip 104 is hybridized with the second semiconductor chip 106). In the example shown in FIG. 1, the conductive pathways 113 are formed vertically, such that the first contacts 110 are respectively vertically aligned with the second contacts 112. It is to be understood, however, that the conductive pathways 113 can be formed in a diagonal manner, in a step-wise manner, etc.

Responsive to the second semiconductor chip 106 being aligned with and placed on the conductive layer 108, the placement tool 118 can be configured to apply a particular amount of pressure (e.g., between 10 to 200 psi) for a particular time duration (e.g., between 1 second and 30 minutes), which can facilitate electrical and mechanical bonding between the first semiconductor chip. For instance, application of such pressure can cause the polymeric layer 108 to cure. Furthermore, heat can be applied (e.g., to the device 102 generally and/or directly to the conductive layer 108) to cure the conductive layer 108 and facilitate electrically and mechanically bonding the first semiconductor chip 104 and the second semiconductor chip 106. An amount of heat applied can be between 40° C. and 200° C. Responsive to the conductive layer 108 being cured, the first semiconductor chip 104 is reversibly hybridized with the second semiconductor chip 106. Thus, electrical signals generated by elements of the second semiconductor chip 106 can traverse the conductive pathways 113 in the conductive polymeric film 108 and be received (and processed) at the first semiconductor chip 104.

Responsive to the first semiconductor chip 104 being reversibly hybridized with the second semiconductor chip 106, the device 102 can be subjected to a testing procedure, such that at least one of the first semiconductor chip 104 or the second semiconductor chip 106 can be characterized as being: 1) suitable for deployment; or 2) defective.

In a non-limiting example, the device 102 can be a portion of an FPA, where the first semiconductor chip 104 is a (previously characterized, “gold standard”) ROIC and the second semiconductor chip 106 is a (uncharacterized) detector. Responsive to the detector being reversibly hybridized with the ROIC by way of the conductive layer 108, the device 102 can be subjected to testing. For example, the detector comprises a plurality of photo-electronic detectors, each having its own respective contact. Light of varying intensities and wavelengths can be applied to the photo-electronic detectors, causing the photo-electronic detectors to generate respective electrical signals. The ROIC can receive these electrical signals by way of the conductive pathways formed in the conductive layer 108, and can perform processing on such electrical signals to generate output signals. The computing device 120 is communicatively coupled with the ROIC by way of the bond pad 111, and receives the output signals. The computing device 120, in an exemplary embodiment, has a program executing thereon that facilitates characterizing the detector based upon the output values received by way of the bond pad 111. That is, the computing device 120 can output an indication that the detector meets operational standards. In another example, the computing device 120 can output data that indicates that the detector is defective. Further, the computing device 120 can output relatively granular information, identifying a pixel (or set of pixels) in the detector that is defective.

Responsive to the at least one of the first semiconductor chip 104 or the second semiconductor chip 106 being characterized, the conductive layer 108 can be removed, thereby breaking the mechanical and electrical bonds formed between the first contacts 110 and the second contacts 112 (e.g., de-hybridizing the first semiconductor chip 104 and the second semiconductor chip 106). In an exemplary embodiment, the conductive layer 108 can be exposed to a solvent, heat, other force, or any suitable combination thereof to remove the conductive layer 108 from between the first semiconductor chip 104 and the second semiconductor chip 106 without damaging either the first semiconductor chip 104 or the second semiconductor chip 106. For instance, the conductive layer 108 may dissolve responsive to the solvent (or heat or other force) being introduced thereto. To that end, for example, when the conductive layer 108 comprises the ACFA, at least one of the first semiconductor chip 104 or the second semiconductor chip 106 can be manufactured to include micro-shims, wherein the micro-shims are spaced upon the upper surface of the first semiconductor chip 104 or the lower surface of the second semiconductor chip 106, resulting in air gaps formed between the ACFA and the one of the first semiconductor chip 104 or the second semiconductor chip 106. Various microfabrication techniques can be employed when forming the micro-shims on the first semiconductor chip 104 or the second semiconductor chip 106. The air gaps facilitate introduction of the solvent to the ACFA. In another exemplary embodiment, the conductive layer 108 can be composed of a material that evaporates responsive to heat being applied thereto, wherein temperature of the heat that causes the conductive polymeric film 104 to evaporate is between, for example, 100° C. and 250° C.

Responsive to the conductive layer 108 being removed, the placement tool 118 lifts the second semiconductor chip 106 from the first semiconductor chip 104, without damaging either the second semiconductor chip 106 or the first semiconductor chip 104. The first semiconductor chip 104 and/or the second semiconductor chip 106 may then be subjected to a cleaning process, removing residual of the conductive layer 108.

It can therefore be ascertained that the first semiconductor chip 104 can be temporarily and reversibly hybridized with the second semiconductor chip 106, allowing for the device 102 to be temporarily formed and subjected to testing, but without the first semiconductor chip 104 and the second semiconductor chip 106 being permanently bonded. For large surface area array electronic devices, this can increase yield and decrease costs associated with conventional fabrication of such devices, as componentry can be relatively exhaustively tested before assembled to form the final device (e.g., a FPA).

Now referring to FIG. 2, an overhead view of the first semiconductor chip 104 responsive to the conductive layer 108 being applied thereto is illustrated. As can be ascertained, the upper side of the first semiconductor chip 104 comprises the first conductive contacts 110a-1101 (first contacts 110) at respective first locations on the first semiconductor chip 104. The conductive layer 108 can be applied to the first semiconductor chip 104, such that the conductive layer 108 adheres to at least a portion of the upper side of the first semiconductor chip 104. For example, when the conductive layer 108 comprises the ACFA, and the first semiconductor chip 104 is fabricated to include the micro-shims mentioned above, the ACFA may adhere to the micro-shims, but may not physically contact the first contacts 110 until the placement tool 118 applies compressive pressure to the device 102. When the conductive layer 108 comprises the conductive polymer, the conductive polymer can be patterned based upon the respective first locations of the first contacts 110 (and the respective second locations of the second contacts 112 relative to the respective first locations of the first contacts 110).

Referring to FIG. 3, a cross-sectional view of a portion 302 of the conductive layer 108 that corresponds to the contact 110a is illustrated, wherein the conductive layer 108 comprises the ACFA. The portion 302 of the ACFA includes a plurality of conductive particles or rods 304a-304d (collectively referred to as conductive rods 304). The conductive rods 304, in an example, can be composed of graphite or other suitable conductive material. The conductive rods 304 can form the conductive pathway 113a. As indicated above, position and orientation of the conductive pathways 113 in the ACFA can be defined during manufacture of the ACFA, and can correspond to known locations of the first contacts 110 and the second contacts 112.

Turning to FIG. 4, a depiction of the placement tool 118 aligning the second semiconductor chip 106 with the conductive layer 108 and placing the second semiconductor chip 106 onto the conductive layer 108 is shown. The placement tool 118, responsive to appropriately aligning the second semiconductor chip 106 with the conductive layer 108, can cause downward pressure to be applied, resulting in compressive pressure being applied to the conductive layer 108. Again, the placement tool 118 can relatively precisely align the second semiconductor chip 106 with the conductive layer 108, such that the second contacts 112 of the second semiconductor chip 106 are electrically coupled to the first contacts 110 of the first semiconductor chip 104 by way of the conductive pathways 113.

With reference to FIG. 5, a cross-section of the portion 302 of the ACFA responsive to the placement tool 118 aligning the second semiconductor chip 106 with the ACFA is depicted. As can be ascertained, the conductive contact 112a of the second semiconductor chip 106 is electrically coupled with the conductive contact 110a of the first semiconductor chip 104 by way of the conductive pathway 113a (formed by the conductive rods 304). When properly aligned, the first contacts 110 are electrically coupled to the second contacts 112 by way of respective individualized conductive pathways, such as that shown in FIG. 5.

Now referring to FIG. 6, responsive to the conductive layer 108 being cured (thereby reversibly hybridizing the first semiconductor chip 104 with the second semiconductor chip 106), the placement tool 118 can be removed, and the resultant device 102 can be subjected to a testing procedure. When the second conductor chip 106 is a detector, responsive to the placement tool 118 being removed, the upper surface of the detector can be exposed to light of particular radiations and intensities (at different portions of the detector). Individual photodetectors in the detectors convert light into respective electrical signals, which traverse through the respective conductive pathways in the conductive layer 108 to the ROIC. The detector can be characterized based upon such electrical signals.

Turning to FIG. 7, reversing the hybridization of the first semiconductor chip 104 with the second semiconductor chip 106 is illustrated. The conductive layer 108 can be exposed to at least one of a solvent, heat, or force, which causes the electrical and mechanical bonds between the first semiconductor chip 104 and the second semiconductor chip 106 to break. For instance, the placement tool 118 can apply tension to the device 102 subsequent or simultaneously to the conductive layer 108 being exposed to the solvent, heat, and/or force, resulting in the second semiconductor chip 106 being electrically and mechanically separated from the first semiconductor chip 104, without either the first semiconductor chip 104 or the second semiconductor chip 106 being damaged.

FIG. 8 depicts the second semiconductor chip 106 being lifted by the placement tool 118 responsive to the conductive layer 108 being removed (e.g., dissolved by way of introduction of the solvent, heat, and/or force to the conductive layer 108). Responsive to the second semiconductor chip 106 being mechanically and electrically separated from the first semiconductor chip 104, the second semiconductor chip 106 and/or the first semiconductor chip 104 (when characterized as being suitable for deployment) can be subjected to a cleaning process, and included in the large surface area array electronic device.

While examples set forth above have referred to the large surface area array electronic device being an FPA that comprises a ROIC and detector, it is to be understood that the reversible hybridization process described herein is well-suited for a variety of different types of large surface area array electronic devices, including stacked memory devices, FPGAs, etc. Moreover, while the examples above have indicated that the first semiconductor chip 104 comprises a ROIC and the second semiconductor chip comprises a corresponding detector, it is to be understood that the first semiconductor chip can comprise the detector and the second semiconductor chip can comprise the ROIC. Furthermore, the testing procedure described herein can be employed to characterize the first semiconductor chip 104, the second semiconductor chip 106, or a combination of the first semiconductor chip 104 and the second semiconductor chip 106.

FIGS. 9-10 illustrate exemplary methodologies relating to characterizing a component of a large surface area array electronic device by way of reversible hybridization. While the methodologies are shown and described as being a series of acts that are performed in a sequence, it is to be understood and appreciated that the methodologies are not limited by the order of the sequence. For example, some acts can occur in a different order than what is described herein. In addition, an act can occur concurrently with another act. Further, in some instances, not all acts may be required to implement a methodology described herein.

Now referring to FIG. 9, an exemplary methodology 900 that facilitates reversibly hybridizing a first semiconductor chip with a second semiconductor chip is illustrated. The methodology 900 starts at 902, and at 904 an ACFA is aligned with a first semiconductor chip and is applied to the first semiconductor chip, wherein the first semiconductor chip comprises first conductive contacts. Alignment is undertaken to align appropriate (pre-existent) conductive pathways in the ACFA with the first conductive contacts of the first semiconductor chip, respectively. As indicated above, for instance, the first semiconductor chip may be a ROIC. At 906, a second semiconductor chip is aligned with and placed on the ACFA, such that the ACFA is between the first semiconductor chip and the second semiconductor chip. The second semiconductor chip comprises second conductive contacts. At 906, alignment is undertaken to align the appropriate conductive pathways in the ACFA with the second contacts of the second semiconductor chip, respectively.

At 908, the first semiconductor chip is caused to bond with the second semiconductor chip by way of the ACFA. With more particularity, at least one of compressive pressure or heat can be applied to the ACFA, thereby curing the ACFA and facilitating electrical and mechanical bonding of the first semiconductor chip with the second semiconductor chip.

At 910, responsive to the first semiconductor chip being bonded with the second semiconductor chip, at least one of the first semiconductor chip or the second semiconductor chip can be tested, wherein testing is based upon at least one electrical signal transitioning between the first semiconductor chip and the second semiconductor chip by way of a conductive path in the conductive paths. At 912, subsequent to testing the at least one of the first semiconductor chip or the second semiconductor chip, the conductive polymeric film can be removed from between the first semiconductor chip and the second semiconductor chip (e.g., a solvent, heat, and/or force can be introduced to the conductive polymeric film causing such film to dissolve evaporate, etc.). The methodology 900 completes at 914.

Now referring to FIG. 10, an exemplary methodology 1000 that facilitates characterizing a detector that is employable to form a portion of a focal plane array is illustrated. The methodology 1000 starts 1002, and at 1004 a ROIC is stably positioned on a platform. At 1006, a conductive polymer is applied to the ROIC. At 1008, the conductive polymer is patterned based upon locations of conductive contacts of the ROIC and locations of conductive contacts of the detector. Such patterning can be undertaken to facilitate creation of individualized conductive pathways between conductive contacts of the ROIC and respective conductive contacts of the detector. At 1010, the detector is aligned with the patterned conductive polymer and placed on the patterned conductive polymer, such that the patterned conductive polymer is between the detector and the ROIC.

At 1012, pressure and/or heat is applied to the conductive polymer to cure the conductive polymer, thus electrically and mechanically bonding the first semiconductor chip to the second semiconductor chip. Accordingly, the first semiconductor chip is temporarily (reversibly) hybridized with the second semiconductor chip.

The 1014, the detector is characterized, for example, based upon values read out from the ROIC when temporarily hybridized with the detector. At 1016, the conductive polymer is nondestructively removed, such that neither the ROIC nor the detector is damaged. The methodology 1000 completes at 1018.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the details description or the claims, such term is intended to be inclusive in a manner similar to the term “comprising” as “comprising” is interpreted when employed as a transitional word in a claim.

What is claimed is:

1. A method comprising:
applying a conductive layer to a first semiconductor chip that comprises first conductive contacts;
aligning a second semiconductor chip with the conductive layer based upon:
respective first locations of the first conductive contacts; and
respective second locations of second conductive contacts of the second semiconductor chip;
placing the second semiconductor chip on the conductive layer such that the conductive layer is between the first semiconductor chip and the second semiconductor chip;
causing the first semiconductor chip to electrically bond with the second semiconductor chip by way of the conductive layer, wherein when the first semiconductor chip is electrically bonded with the second semiconductor chip, the first conductive contacts are electrically coupled to the second conductive contacts by way of respective individualized conductive pathways in the conductive layer;
responsive to the first semiconductor chip being electrically bonded with the second semiconductor chip, testing at least one of the first semiconductor chip or the second semiconductor chip, wherein the testing is based upon at least one electrical signal traversing from the second semiconductor chip to the first semiconductor chip by way of a conductive path in the individualized conductive paths; and
subsequent to testing the at least one of the first semiconductor chip or the second semiconductor chip, removing the conductive layer from between the first semiconductor chip and the second semiconductor chip.

2. The method of claim 1, wherein the first semiconductor chip comprises a readout integrated circuit, and the second semiconductor chip comprises an array of sensors.

3. The method of claim 2, wherein the array of sensors is an array of photodetectors.

4. The method of claim 1, wherein the second semiconductor chip comprises a plurality of memory cells.

5. The method of claim 1, wherein the conductive layer comprises an anisotropic conductive polymer.

6. The method of claim 5, wherein the anisotropic conductive polymer is polyaniline.

7. The method of claim 1, wherein causing the first semiconductor chip to electrically bond with the second semiconductor chip by way of the conductive layer comprises applying compressive pressure to the conductive layer responsive to placing the second semiconductor chip on the conductive layer.

8. The method of claim 7, wherein the compressive pressure applied to the conductive layer is between 10 and 200 psi.

9. The method of claim 1, wherein causing the first semiconductor chip to electrically bond with the second semiconductor chip by way of the conductive layer comprises applying heat to the conductive layer responsive to placing the second semiconductor chip on the conductive layer.

10. The method of claim 9, wherein the heat applied to the conductive layer is between 40 and 200 degrees Celsius.

11. The method of claim 1, wherein removing the conductive layer from between the first semiconductor chip and the second semiconductor chip comprises at least one of:
exposing the conductive layer to a solvent, wherein exposing the conductive layer to the solvent causes the conductive layer to dissolve in the solvent; or
applying at least one of heat or pressure to the conductive layer.

12. The method of claim 1, further comprising:
responsive to applying the conductive layer to the first semiconductor chip and prior to placing the second semiconductor chip on the conductive layer, patterning the conductive layer based upon:
the respective first locations of the first conductive contacts on the first semiconductor chip; and
the respective second locations of the second conductive contacts on the second semiconductor chip.

13. An apparatus comprising:
a first semiconductor chip that comprises first conductive contacts on an upper surface of the first semiconductor chip;
a conductive layer positioned on the upper surface of the first semiconductor chip; and
a second semiconductor chip that comprises second conductive contacts on a lower surface of the second semiconductor chip, the lower surface of the second semiconductor chip positioned on the conductive layer and opposing the upper surface of the first semiconductor chip, the conductive layer mechanically and electrically bonds the first semiconductor chip with the second semiconductor chip, wherein respective conductive pathways electrically couple the first contacts to the second contacts, and wherein the first semiconductor chip is reversibly hybridized with the second semiconductor chip by way of the conductive layer.

14. The apparatus of claim 13, the conductive layer comprising polyaniline.

15. The apparatus of claim 13, the first semiconductor chip comprising a readout integrated circuit of a focal plane array (FPA), the second semiconductor chip comprising a detector of the FPA.

16. The apparatus of claim 13, the first semiconductor chip comprising an exposed bond pad, wherein the conductive layer fails to cover the exposed bond pad.

17. The apparatus of claim 13, the conductive layer patterned based upon respective first locations of the first contacts on the first semiconductor chip relative to respective second locations of the second contacts on the second semiconductor chip.

18. The apparatus of claim 13, the first semiconductor chip comprising a first memory array, the second semiconductor chip comprising a second memory array.

19. The apparatus of claim 13, the conductive polymeric film having a thickness of between 0.5 microns and 250 microns.

20. A method for characterizing a detector of a focal plane array (FPA), the detector comprises first conductive contacts at respective first locations of the detector, the method comprising:
placing a conductive polymer on a readout integrated circuit (ROIC), the ROIC comprises second conductive contacts at respective second locations of the ROIC;
patterning the conductive polymer based upon the respective first locations of the first conductive contacts of the detector and the respective second locations of the second conductive contacts of the detector;
responsive to patterning the conductive polymer, aligning and placing the detector on the patterned conductive polymer, the patterned conductive polymer positioned between the ROIC and the detector;
responsive to aligning and placing the detector on the conductive polymer, curing the conductive polymer, wherein curing the conductive polymer facilitates electrically bonding the first conductive contacts with the second conductive contacts by way of respective individualized conductive pathways;
causing an electrical signal generated by the detector to traverse a conductive pathway in the individualized conductive pathways from a first contact in the first conductive contacts to a second contact in the second conductive contacts;
reading a value from the ROIC based upon the electrical signal;
characterizing the detector as being one of deployable or defective based upon the value read from the ROIC; and
responsive to characterizing the detector, removing the conductive polymer from between the ROIC and the detector.
